(19) United States
(12) Patent Application Publication
(10) Pub. No.: US 2013/0198585 A1
(43) Pub. Date: Aug. 1, 2013

(54) METHOD OF, AND APPARATUS FOR, IMPROVED DATA INTEGRITY

(71) Applicants: Peter J. BRAAM, Nederland, CO (US); Nathaniel RUTMAN, Portland, OR (US)

(72) Inventors: Peter J. BRAAM, Nederland, CO (US); Nathaniel RUTMAN, Portland, OR (US)

(73) Assignee: Xyratex Technology Limited, Havant (GB)

(21) Appl. No.: 13/364,150

(22) Filed: Feb. 1, 2012

(51) Int. Cl. H03M 13/11; G06F 11/10

(52) U.S. Cl. 714/763; 714/E11.034

(57) ABSTRACT

There is provided a method of writing data to a data sector of a storage device. The data sector has at least one parity sector associated therewith, each sector being configured to include a data field and a data integrity field. The data integrity field including a guard field, an application field and a reference field. The method includes providing data to be written to an intended sector; generating, for the intended sector, version information for the sector; generating a version vector based on the version information for the data sector; and writing the data to the data field of the data sector; writing the version information to the application field of the data sector; and writing the version vector to the application field of the parity sector.

The present invention relates to a method of, and apparatus for, version mirroring. In particular, the present invention relates to a method of, and apparatus for, version mirroring using the T10 protocol.

Data integrity is a core requirement for a reliable storage system. The ability to prevent and, if necessary, identify and correct data errors and corruptions is essential for operation of storage systems ranging from a simple hard disk drive up to large mainframe storage arrays.

A typical hard disk drive comprises a number of addressable units, known as sectors. A sector is the smallest externally addressable portion of a hard disk drive. Each sector typically comprises 512 bytes of usable data. However, recent developments under the general term “advanced format” sectors enable support of sector sizes up to 4 k bytes. When data is written to a hard disk drive, it is usually written as a block of data, which comprises a plurality of contiguous sectors.

A hard disk drive is an electro-mechanical device which may be prone to errors and or damage. Therefore, it is important to detect and correct errors which occur on the hard disk drive during use. Commonly, hard disk drives set aside a portion of the available storage in each sector for the storage of error correcting codes (ECCs). This data is also known as protection information. The ECC can be used to detect corrupted or damaged data and, in many cases, such errors are recoverable through use of the ECC. However, for many cases such as enterprise storage architectures, the risks of such errors occurring are required to be reduced further.

One approach to improve the reliability of a hard disk drive storage system is to employ redundant arrays of inexpensive disk (RAID). Indeed, RAID arrays are the primary storage architecture for large, networked computer storage systems.

The RAID architecture was first disclosed in “A Case for Redundant Arrays of Inexpensive Disks (RAID)”, Patterson, Gibson, and Katz (University of California, Berkeley). RAID architecture combines multiple small, inexpensive disk drives into an array of disk drives that yields performance exceeding that of a single large drive.

There are a number of different RAID architectures, designated as RAID-1 through RAID-6. Each architecture offers disk fault-tolerance and offers different trade-offs in terms of features and performance. In addition to the different architectures, a non-redundant array of disk drives is referred to as a RAID-0 array. RAID controllers provide data integrity through redundant data mechanisms, high speed through streamlined algorithms, and accessibility to stored data for users and administrators.

RAID architecture provides data redundancy in two basic forms: mirroring (RAID 1) and parity (RAID 3, 4, 5 and 6). The implementation of mirroring in RAID 1 architectures involves creating an identical image of the data on a primary disk on a secondary disk. The contents of the primary and secondary disks in the array are identical. RAID 1 architecture requires at least two drives and has increased reliability when compared to a single disk. Since each disk contains a complete copy of the data, and can be independently addressed, reliability is increased by a factor equal to the power of the number of independent mirrored disks, i.e. in a two disk arrangement, reliability is increased by a factor of four.

RAID 3, 4, 5, or 6 architectures generally utilise three or more disks of identical capacity. In these architectures, two or more of the disks are utilised for reading/writing of data and one or more of the disks store parity information. Data interleaving across the disks is usually in the form of data “striping” in which the data to be stored is broken down into blocks called “stripe units”. The “stripe units” are then distributed across the disks.

Therefore, should one of the disks in a RAID group fail or become corrupted, the missing data can be recreated from the data on the other disks. The data may be reconstructed through the use of the redundant “stripe units” stored on the remaining disks. However, RAID architectures utilising parity configurations need to generate and write parity information during a write operation. This may reduce the performance of the system.

However, even in a multiply redundant system such as a RAID array, certain types of errors and corruptions cannot be detected or reported by the RAID hardware and associated controllers.

A number of errors and corruptions fall into this category. One such error is a misdirected write. This is a situation where a block of data which is supposed to be written to a first location is actually written to a second, incorrect, location. In this case, the system will not return a disk error because there has not, technically, been any corruption or hard drive error. However, on a data integrity level, the data at the second location has been overwritten and lost, and old data is still present at the first location. These errors remain undetected by the RAID system.

A misdirected read can also cause corruptions. A misdirected read is where data intended to be read from a first location is actually read from a second location. In this situation, parity corruption can occur due to read-modify-write (RMW) operations. Consequently, missing drive data may be rebuilt incorrectly.

Another data corruption which can occur is a torn write. This situation occurs where only a part of a block of data intended to be written to a particular location is actually written. Therefore, the data location comprises part of the new data and part of the old data. Such a corruption is, again, not detected by the RAID system.

Additionally, data is not always protected by ECC or CRC (cyclic redundancy check) systems. Therefore, such data can become corrupted when being passed from hardware such as the memory and central processing unit (CPU), via hardware adapters and RAID controllers. Again, such an error will not be flagged by the RAID system.

When silent data corruption has occurred in a RAID system, a further problem of parity pollution may occur. This is when parity information is calculated from (unknowingly) corrupt data. In this case, the parity cannot be used to correct the corruption and restore the original, non-corrupt, data.

Certain RAID systems (for example, RAID 6 systems) can be configured to detect and correct such errors. However, in order to do this, a full stripe read is required for each sub stripe access. This requires significant system resources and time. In addition, certain storage protocols exist which are able to address such issues at least in part. For example, block checksums can be utilised which are able to detect torn writes.

One further corruption that can occur is a lost write. This occurs when firmware returns a success code to indicate successful completion of a write, but not actually carry out the write process. Such an error cannot be detected using standard block checksums because the disk block retains data and checksum written on a previous occasion and so the data and checksum are consistent.

One approach to the problem of lost writes is what is known as version mirroring. Version mirroring is where each data block which belongs to a RAID stripe contains a version number. The version number is changed with every write to the block, and a parity block is updated to include a list of version numbers of all blocks that are protected thereby.

In use, whenever a data block is read, its version number is compared to the corresponding version number stored in the parity block. If a mismatch occurs, the newer block will have a higher version number and can be used to reconstruct the other data block. This approach is outlined theoretically in “Parity Lost and Parity Regained”, A. Krioukov et al, FAST '08.

However, to date, no suitable method of reliably employing such a technique in a RAID array has been proposed. Therefore, to date, known storage systems suffer from a technical problem that certain data corruptions cannot be detected reliably using methods which can be implemented on existing storage systems.

According to a first aspect of the present invention, there is provided a method of writing data to a data sector of a storage device, the data sector having at least one parity sector associated therewith, each sector being configured to comprise a data field and a data integrity field, the data integrity field comprising a guard field, an application field and a reference field, the method comprising: providing data to be written to an intended sector; generating, for said intended sector, version information for said sector; writing said data to the data field of the data sector; writing said version information to the application field of the data sector; generating a version vector based on said version information for said data sector; and writing said version vector to the application field of the parity sector.

In one embodiment, the method further comprises writing said data in units of blocks, wherein each block comprises a plurality of sectors.

In one embodiment, each sector within a given block is allocated the same version number.

In one embodiment, the version number of a sector is changed each time said sector is written to.

In one embodiment, the version number is incremented each time the sector is written to.

In one embodiment, the version number is changed randomly each time the sector is written to.

In one embodiment, the version number is changed randomly for all blocks.

In one embodiment, the version number is changed randomly independently for each block or group of blocks.

In one embodiment, the version number is incremented and randomly selected.

In one embodiment, the method further comprises: writing said data in units of stripe units, each stripe unit comprising a plurality of blocks.

In one embodiment, said intended sector comprises part of a stripe unit and the method comprises, after said step of providing: reading version information from stripe units associated with said stripe unit; reading the version vector associated with said stripe units; determining whether a mismatch has occurred between the version information and the version vector and, if a mismatch has occurred, correcting said data.

In one embodiment, said version vector comprises the version information for the or each data sector.

In one embodiment, said version vector comprises a reduction function of said version information.

According to a second aspect of the present invention, there is provided a method of reading data from a sector of a storage device, the data sector having at least one parity sector associated therewith, each sector being configured to comprise a data field and a data integrity field, the data integrity field comprising a guard field, an application field and a reference field, the method comprising: executing a read request for reading of data from a data sector; reading version information from the application field of said data sector; reading version vector from the application field of a parity sector associated with said data sector; determining whether a mismatch has occurred between the version information and the version vector and, if a mismatch has occurred, correcting said data; and reading the data from said data sector.

According to a third aspect of the present invention, there is provided a controller operable to write data to a data sector of a storage device, the data sector having at least one parity sector associated therewith, each sector being configured to comprise a data field and a data integrity field, the data integrity field comprising a guard field, an application field and a reference field, the controller being operable to provide data to be written to an intended sector, generate, for said intended sector, version information for said sector, to write said data to the data field of the data sector, to write said version information to the application field of the data sector, to generate a version vector based on said version information for said data sector; and to write said version vector to the application field of the parity sector.

According to a fourth aspect of the present invention, there is provided a controller operable to read data from a sector of a storage device, the data sector having at least one parity sector associated therewith, each sector being configured to comprise a data field and a data integrity field, the data integrity field comprising a guard field, an application field and a reference field, the controller being operable to execute a read request for reading of data from a data sector, to read version information from the application field of said data sector, to read a version vector from the application field of a parity sector associated with said data sector, to determine whether a mismatch has occurred between the version information and the version vector and, if a mismatch has occurred, to correct said data and to read the data from said data sector.

According to a fifth aspect of the invention, there is provided a data storage apparatus comprising at least one storage device and the controller of the third or fourth aspects.

According to a sixth aspect of the present invention, there is provided a computer program product executable by a programmable processing apparatus, comprising one or more software portions for performing the steps of the first and/or second aspects.

According to a seventh aspect of the present invention, there is provided a computer usable storage medium having a computer program product according to the sixth aspect stored thereon.

Embodiments of the present invention will now be described in detail with reference to the accompanying drawings, in which:

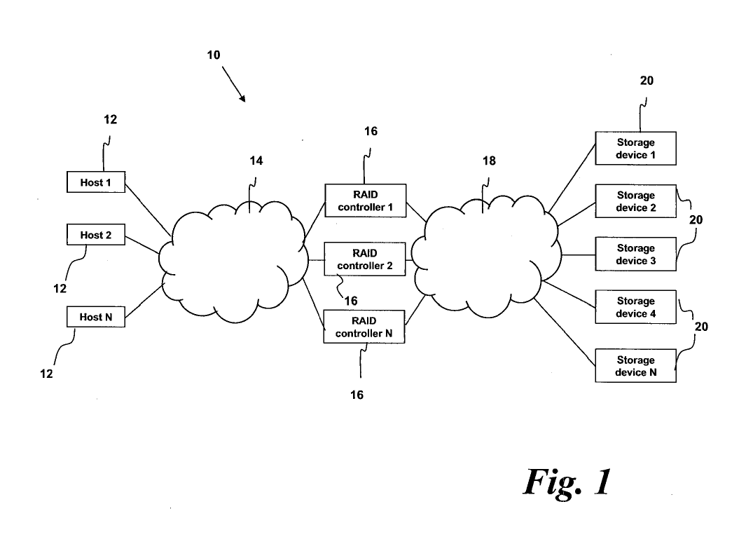

FIG. 1 is a schematic diagram of a networked storage resource;

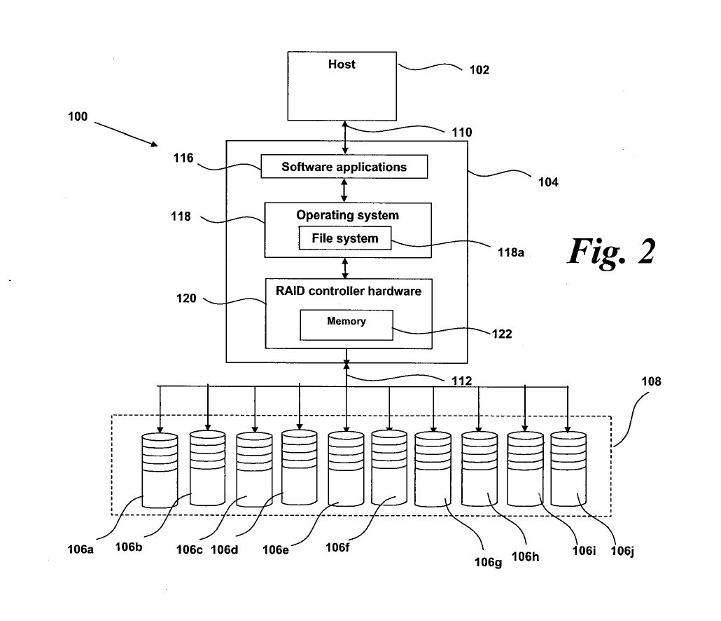

FIG. 2 is a schematic diagram showing a RAID controller of an embodiment of the present invention;

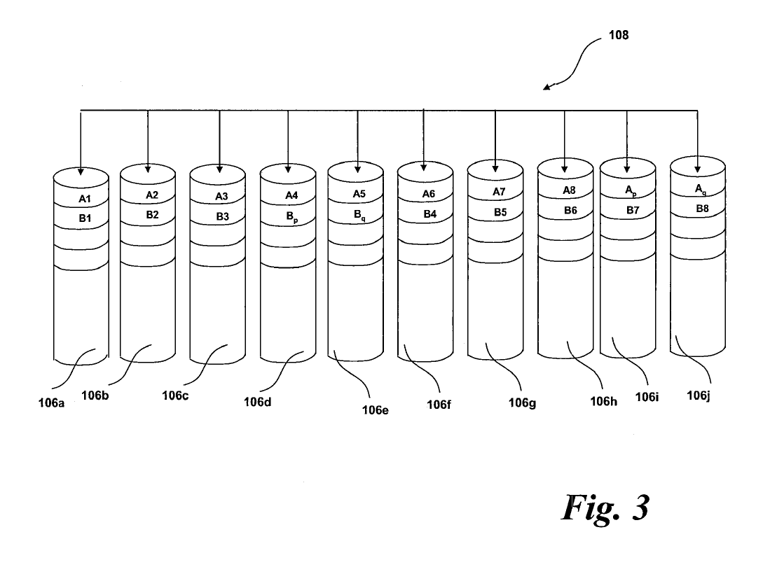

FIG. 3 is a schematic diagram of the mapping between storage sector indices in a RAID 6 arrangement;

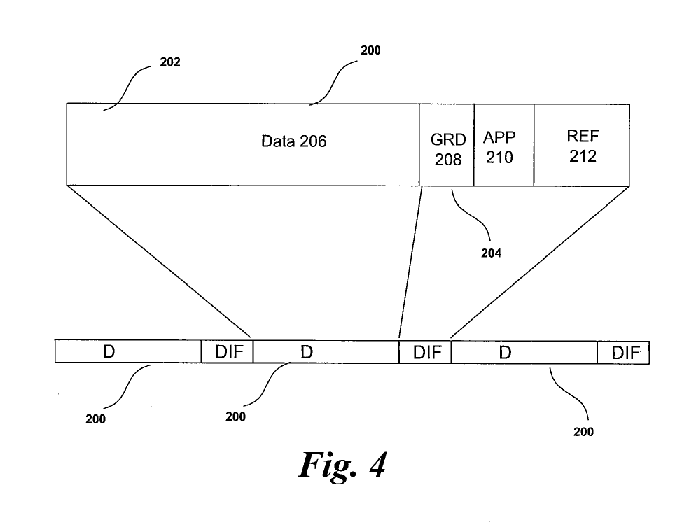

FIG. 4 is a schematic diagram of a sector amongst a plurality of sectors in a storage device;

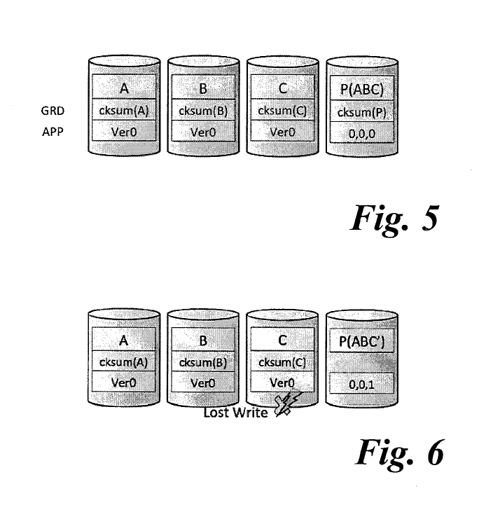

FIG. 5 is a schematic diagram of version numbering according to an embodiment of the invention;

FIG. 6 is a schematic diagram of the process of using version numbering to identify a lost write according to an embodiment of the invention;

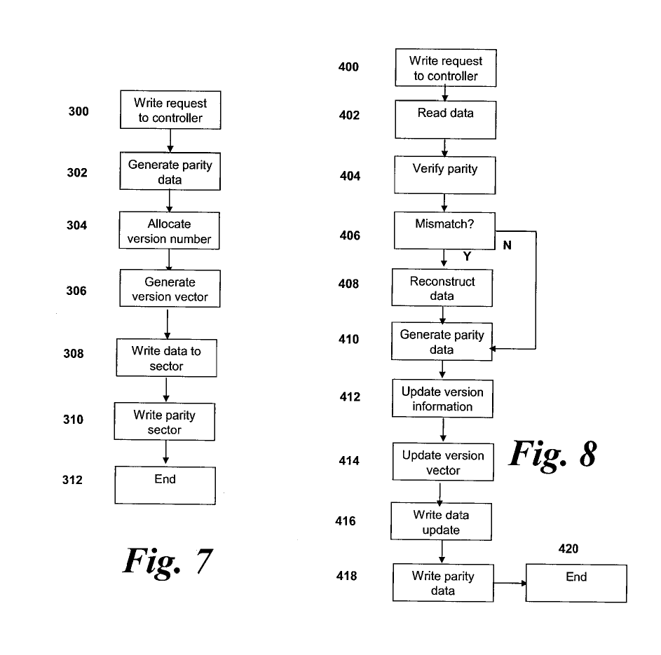

FIG. 7 is a flow diagram showing a write operation according to an embodiment of the present invention;

FIG. 8 is a flow diagram showing a further write operation according to an embodiment of the present invention;

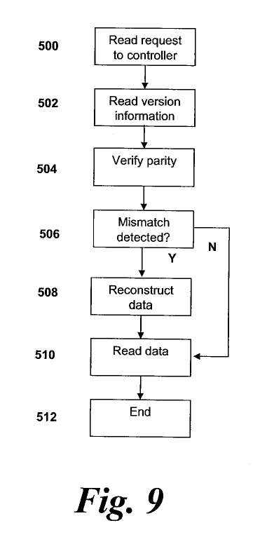

FIG. 9 is a flow diagram showing a read operation according to an embodiment of the present invention;

FIG. 1 shows a schematic illustration of a networked storage resource 10 in which the present invention may be used. However, it is to be appreciated that a networked storage resource is only one possible implementation of a storage resource which may be used with the present invention. Indeed, the storage resource need not necessarily be networked and may comprise, for example, systems with local or integrated storage resources such as, non-exhaustively, a local server, personal computer, laptop, so-called “smartphone” or personal data assistant (PDA).

The networked storage resource 10 comprises a plurality of hosts 12. The hosts 12 are representative of any computer systems or terminals that are operable to communicate over a network. Any number of hosts 12 may be provided; N hosts 12 are shown in FIG. 1, where N is an integer value.

The hosts 12 are connected to a first communication network 14 which couples the hosts 12 to a plurality of RAID controllers 16. The communication network 14 may take any suitable form, and may comprise any form of electronic network that uses a communication protocol; for example, a local network such as a LAN or Ethernet, or any other suitable network such as a mobile network or the internet.

The RAID controllers 16 are connected through device ports (not shown) to a second communication network 18, which is also connected to a plurality of storage devices 20. The RAID controllers 16 may comprise any storage controller devices that process commands from the hosts 12 and, based on those commands, control the storage devices 20. RAID architecture combines a multiplicity of small, inexpensive disk drives into an array of disk drives that yields performance that can exceed that of a single large drive. This arrangement enables high speed access because different parts of a file can be read from different devices simultaneously, improving access speed and bandwidth. Additionally, each storage device 20 comprising a RAID array of devices appears to the hosts 12 as a single logical storage unit (LSU) or drive.

The operation of the RAID controllers 16 may be set at the Application Programming Interface (API) level. Typically, Original Equipment Manufactures (OEMs) provide RAID networks to end users for network storage. OEMs generally customise a RAID network and tune the network performance through an API.

Any number of RAID controllers 16 may be provided, and N RAID controllers 16 (where N is an integer) are shown in FIG. 1. Any number of storage devices 20 may be provided; in FIG. 1, N storage devices 20 are shown, where N is any integer value.

The second communication network 18 may comprise any suitable type of storage controller network which is able to connect the RAID controllers 16 to the storage devices 20. The second communication network 18 may take the form of, for example, a SCSI network, an iSCSI network or fibre channel.

The storage devices 20 may take any suitable form; for example, tape drives, disk drives, non-volatile memory, or solid state devices. Although most RAID architectures use hard disk drives as the main storage devices, it will be clear to the person skilled in the art that the embodiments described herein apply to any type of suitable storage device. More than one drive may form a storage device 20; for example, a RAID array of drives may form a single storage device 20. The skilled person will be readily aware that the above features of the present embodiment could be implemented in a variety of suitable configurations and arrangements.

The RAID controllers 16 and storage devices 20 also provide data redundancy. The RAID controllers 16 provide data integrity through a built-in redundancy which includes data mirroring. The RAID controllers 16 are arranged such that, should one of the drives in a group forming a RAID array fail or become corrupted, the missing data can be recreated from the data on the other drives. The data may be reconstructed through the use of data mirroring. In the case of a disk rebuild operation, this data is written to a new replacement drive that is designated by the respective RAID controller 16.

FIG. 2 shows a schematic diagram of an embodiment of the present invention. A storage resource 100 comprises a host 102, a RAID controller 104, and storage devices 106a, 106b, 106c, 106d, 106e, 106f, 106g and 106h which, together, form part of a RAID 6 array 108.

The host 102 is connected to the RAID controller 104 through a communication network 110 such as an Ethernet and the RAID controller 104 is, in turn, connected to the storage devices 106a -j via a storage network 112 such as an iSCSI network.

The host 102 comprises a general purpose computer (PC) which is operated by a user and which has access to the storage resource 100.

The RAID controller 104 comprises a software application layer 116, an operating system 118 and RAID controller hardware 120. The software application layer 116 comprises software applications including the algorithms and logic necessary for the initialisation and run-time operation of the RAID controller 104. The software application layer 116 includes software functional blocks such as a system manager for fault management, task scheduling and power management. The software application layer 116 also receives commands from the host 102 (e.g., assigning new volumes, read/write commands) and executes those commands. Commands that cannot be processed (because of lack of space available, for example) are returned as error messages to the user of the host 102.

The operating system 118 utilises an industry-standard software platform such as, for example, Linux, upon which the software applications forming part of the software application layer 116 can run. The operating system 118 comprises a file system 118a which enables the RAID controller 104 to store and transfer files and interprets the data stored on the primary and secondary drives into, for example, files and directories for use by the operating system 118. This may comprise a Linux-based system such as LUSTRE.

The RAID controller hardware 120 is the physical processor platform of the RAID controller 104 that executes the software applications in the software application layer 116. The RAID controller hardware 120 comprises a microprocessor, memory 122, and all other electronic devices necessary for RAID control of the storage devices 106a-j.

The storage devices 106a -j forming the RAID array 108 are shown in more detail in FIG. 3. Each storage device 106a-j comprises a hard disk drive generally of high capacity, for example, 1 TB or larger. Each device 106a -j can be accessed by the host 102 through the RAID controller 104 to read/write data. In this example, a RAID 6 array is illustrated comprising eight drives and two parity drives. Therefore, this arrangement is known as a RAID 6 (8+2) configuration. However, the skilled person would readily understand that the present invention could be applied to any suitable RAID array such as RAID 5 or any other suitable storage protocol.

As shown in FIG. 3, data is stored on the RAID 6 array 108 in the form of stripe units (also known as RAID chunks). Each data stripe A, B comprises ten separate stripe units distributed across the storage devices—stripe A comprises stripes A1-A8 and parity stripe units Aₚ and A_{q}. Stripe B comprises stripe units B1 to B8 and parity stripe unit Bₚ and B_{q}. Therefore, the stripe units comprising each stripe (A1-A8 or B1-B8 respectively) are distributed across a plurality of disk drives, together with parity information Aₚ, A_{q}, Bₚ and B_{q} respectively. This provides data redundancy.

The size of a stripe unit can be selected based upon a number of criteria, depending upon the demands placed upon the RAID array 108, e.g. workload patterns or application specific criteria. Common stripe unit sizes generally range from 16 K up to 256 K. In this example, 128 K stripe units are used. The size of each stripe A, B is then determined by the size of each stripe unit in the stripe multiplied by the number of non-parity data storage devices in the array (which, in this example, is eight). In this case, if 128 K stripe units are used, each RAID stripe would comprise 8 data stripe units (plus 2 parity stripe units) and each RAID stripe A, B would be 1 MB wide.

However, the stripe size is not material to the present invention and the present example is given as a possible implementation only. Alternative arrangements may be used. Any number of drives or stripe unit sizes may be used.

The following embodiment of the invention may be utilised with the above RAID arrangement. In the following description, for brevity, a single storage device 106a will be referred to. However, the embodiment of the invention is equally applicable to other arrangements; for example, the storage device 106a may be a logical drive, or may be a single hard disk drive.

Storage on a storage device 106a-j comprises a plurality of sectors (also known as logical blocks). A sector is the smallest unit of storage on the storage device 106a-j. A stripe unit will typically comprise a plurality of sectors.

FIG. 4 shows the format of a sector 200 of a storage device 106a. The sector 200 comprises a data field 202 and a data integrity field 204. Depending upon the file system used, each sector 200 may correspond to a logical block.

As set out above, the term “storage device” in the context of the following description may refer to a logical drive which is formed on the RAID array 108. In this case, a sector refers to a portion of the logical drive created on the RAID array 108. The following embodiment of the present invention is applicable to any of the above described arrangements.

The term “sector” used herein, whilst described in an embodiment with particular reference to 520 byte sector sizes, is generally applicable to any sector sizes within the scope of the present invention. For example, some modern storage devices comprise 4 KB data sectors and a 64 byte data integrity field. Therefore, the term “sector” is merely intended to indicate a portion of the storage availability on a storage device within the defined storage protocols and is not intended to be limited to any of the disclosed examples. Additionally, sector may be used to refer to a portion of a logical drive, i.e. a virtual drive created from a plurality of physical hard drives linked together in a RAID configuration.

In this embodiment, the storage device 106 is formatted such that each sector 200 comprises 520 bytes (4160 bits) in accordance with the American National Standards Institute's (ANSI) T10-DIF (Data Integrity Field) specification format. The T10-DIF format specifies data to be written in blocks or sectors of 520 bytes. The 8 additional bytes in the data integrity field provide additional protection information (PI), some of which comprises a checksum that is stored on the storage device together with the data. The data integrity field is checked on every read and/or write of each sector. This enables detection and identification of data corruption or errors. However, the standard PI used with the T10-DIF format is unable to detect lost or torn writes.

ANSI T10-DIF provides three types of data protection: logical block guard for comparing the actual data written to disk, a logical block application tag and a logical block reference tag to ensure writing to the correct virtual block. The logical block application tag is not reserved for a specific purpose.

A further extension to the T10-DIF format is the T-10 DIX (data integrity extension) format which enables 8 bytes of extension information to enable PI potentially to be piped from the client-side application directly to the storage device.

As set out above, the data field 202, in this embodiment, is 512 bytes (4096 bits) long and the data integrity field 204 is 8 bytes (64 bits) long. The data field 202 comprises user data 206 to be stored on the storage device 106a-j. This data may take any suitable form and, as described with reference to FIGS. 2 and 3, may be divided into a plurality of stripe units spread across a plurality of storage devices 106a-j. However, for clarity, the following description will focus on the data stored on a single storage device 106.

In a T10-based storage device, the data integrity field 204 comprises a guard (GRD) field 208, an application (APP) field 210 and a reference (REF) field 212.

The GRD field 208 comprises 16 bits of ECC, CRC or parity data for verification by the T10-configured hardware. In other words, sector checksums are included in the GRD field in accordance with the T10 standard. The format of the guard tag between initiator and target is specified as a CRC using a well-defined polynomium. The guard tag type is required to be a per-request property, not a global setting.

The REF field 212 comprises 32 bits of location information that enables the T10 hardware to prevent misdirected writes. In other words, the physical identity for the address of each sector is included in the REF field of that sector in accordance with the T10 standard.

The APP field 210 comprises 16 bits reserved for application specific data. In practice, this field is rarely used. However, the present invention contemplates, for the first time, that the APP field 210 can be utilised to improve data integrity.

In the present invention, the available bits in the APP field 210 are used to provide version mirroring to improve data integrity. In general, version minoring is where each block (comprising, in this embodiment, 8 sectors) belonging to a RAID stripe contains a version number. The version number is the same for each sector within a block. A parity block is also provided which comprises a copy of the version number for each block associated with that parity block.

The version number is modified in some way with every write to the sector. The parity sector is also updated to include a list of version numbers of all sectors that are protected thereby. Whenever a sector is read, the parity sector is checked. If an error is detected in the version numbers, then a torn write may have occurred and the data error can be reconstructed using the parity sectors and the uncorrupted sectors in the stripe.

A schematic arrangement of version minoring is shown in FIG. 5 where a three blocks A, B, C and a parity block P are shown. Only three data blocks are shown here. However, in the RAID 6 eight storage device array as described above, eight blocks and two parity blocks would be present.

Further, in practice, each stripe unit will comprise a plurality of Linux blocks (each of 4 KB), each of which comprise 8 sectors as described with reference to FIG. 4. Therefore, as will be appreciated by the skilled person, a 128 K stripe unit as described will comprise 32 4 KB Linux blocks and 256 sectors as described with reference to FIG. 4.

As shown, in each case the GRD field 208 comprises CRC checksum data for each sector. In addition, the REF field 212 (not shown in FIG. 5) of each sector forming part of the stripe unit includes the physical identity for the address of that respective sector.

In this embodiment, the APP fields 210 of each of the blocks A, B, C comprises version information. In this embodiment, the version information is the same for each sector comprising the blocks A, B, C. In this case each block A, B, C has only been written to a single time and so the version number is 0 in each case. As a result, the parity sector P comprises a parity version vector comprising each of the version numbers of A, B and C, or (0, 0, 0). In general, the parity data in the APP parity sector 210 will comprise some reduction function or convolution of the version numbers for A, B and C due to the limited data space available to store complex parity data.

It is to be appreciated that FIG. 5 illustrates version mirroring on a block scale.

However, in practice, each stripe unit comprises (in this embodiment) 32 Linux blocks and 256 T10 sectors.

Each sector has the same version number which enables, amongst other things, detection of torn writes within a block. Torn writes occur when only some sectors within a block are written, and cannot be detected by conventional block checksums as used under systems such as Lustre. Torn writes also cannot be detected using conventional T10 checksums.

An example of the operation of version mirroring will be described with reference to FIG. 6 which illustrates the arrangement of FIG. 5 after a write process in which a lost write has occurred. A previous attempt to modify block C (to C′) has resulted in a lost write. As a result, the version number for C remains 0, whereas the APP field 210 of the parity block P has been updated to reflect the state of C as having been updated, i.e. to reflect that C has been modified and has an updated version number of 1. Therefore the parity data in the APP field 210 comprises (0, 0, 1).

Consequently, consider the situation where a subsequent write to A (to generate A′) is processed starting from the configuration in FIG. 6. In order to do so, B and C are read to construct the new parity data P (A′BC′). However, P first is read to verify the version numbers prior to writing P′.

At this point, a version mismatch will be identified. However, the lost write, C′, can be reconstructed from P. Then the parity data P′(A′BC′) can be correctly calculated. A′ can then be written, and P′ can be written to the parity block.

As shown above, the use of version numbers in the APP field 210 of the data integrity field 204 of the sectors 200 comprising a block can be utilised to detect lost writes and reconstruct the data.

With regard to torn writes (i.e. where not all of the sectors in a block are written to) cannot be directly detected by conventional T10 sector checksums. As noted, a Linux block comprises 4096 bytes of data instead of 512 bytes as is the case for a T10 sector. Therefore, sector checksums alone (i.e. the data in the GRD field 208) does not provide protection against torn writes within a block (where not all the sectors are written). However, the use of version numbers enables such errors to be detected. By assigning the same version number to each of the eight sectors forming a 4 KB block, a torn write can be detected by a discrepancy in the version numbering within a block.

In summary, by storing version mirroring information in the T10-DIF APP (application) field 210 of each sector 200 comprising a Linux block and forming part of a stripe unit, and a copy of the version information from each block (the “version vector”) in the APP field of the parity block, silent data corruption can be reliably detected.

This “vertical” redundancy of information, combined with the “horizontal” redundancy of version mirroring using the parity block, provides complete protection against torn writes in place of block checksums, but requires reading of at least the APP field of the parity blocks, to validate the versions of the data blocks.

The version information used in the APP field 210 of each sector 200 may be generated in a number of ways. A number of alternative approaches are listed below. However, this list is intended to be non-exhaustive and non-limiting and the skilled person would be readily aware of other approaches that may be used.

### 1. Monotonically Increasing Version Number

In this arrangement, the version numbering starts at 1 for each stripe unit and increases by 1 for every rewrite of the stripe unit. The parity version vector stored in the APP field 210 of the parity block must represent the versions of each stripe unit. Therefore, for an 8-stripe RAID, there would be 2 bits per version in the parity version vector.

This arrangement is sufficient to detect torn writes in general, because 4 torn writes would need to be missed in a row to result in overrun. However, the version vector or the stripe unit version must be read at each full or partial stripe write in order to know the value to increment.

As a further benefit, the “reconstruct-write” approach used by RAID 6 requires re-reading all of the sectors to recompute the parity data. Therefore, the old versions are obtained at no additional cost in the case of a partial write.

### 2. Random Version Number

The same random version number is applied to each block and to the corresponding parity block. If the version number for any sector within a block differs, then it represents a torn write.

This approach has the advantage that, for a full stripe write, no reading of an existing version is required. Instead, a new random number is generated. For partial stripe write, however, all versions must be updated, turning all partial-stripe writes into full-stripe writes.

### 3. Per-Block Random Version Number

The approach avoids the requirement to obtain the old version number as required in option 1. However, with only 2 bits per random number, there remains a 25% chance of missing a torn write.

An alternative would be to utilise the APP field 210 in both of the parity blocks (blocks P and Q) to obtain 4 bits per stripe unit. However, this would require reading both parity blocks on every read.

### 4. Combined Random and Incremental

This approach takes elements of the above examples. By way of example, 14 high bits could be utilised for a random number and 2 low bits for a per-sector incremental. The 2 low bits are mirrored in the version vector. The version vector must still be read for partial-stripe writes (to learn the old version, free with RAID 6 reconstruct-writes), but for a full stripe rewrite a new random number is chosen for the high bits. This approach would eliminate the need to read anything for a full-stripe write.

Whilst the above examples have been given to illustrate operation of the present invention, other approaches may be used. For example, the version number may be based on the RPC request number or on a timestamp. These variations and alternatives are intended to fall within the scope of the present invention.

The operation of a method according to the present invention will now be described with reference to FIGS. 7, 8 and 9.

FIG. 7 shows a flow diagram of the method for writing a full stripe of data to the RAID array 108 with improved data integrity. FIG. 8 shows a flow diagram of the method for updating data on the storage device 106a and identifying silent data corruptions. FIG. 9 illustrates a flow diagram of a method for reading data from the RAID array 108.

The steps of writing a full stripe of data to the RAID array will be discussed with reference to FIG. 7.

### Step 300: Write Request to Controller

At step 300, the host 102 generates a write request for a specific volume (e.g.

storage device 106a) to which it has been assigned access rights. The request is sent via communication network 110 to the host ports (not shown) of the RAID controller 104. The write command is then stored in a local cache (not shown) forming part of the RAID controller hardware 120 of the RAID controller 104.

The RAID controller 104 is programmed to respond to any commands that request write access to the storage device 106a. The RAID controller 104 processes the write request from the host 102 and determines the target identifying address of the stripe to which it is intended to write that data to.

The method proceeds to step 302.

### Step 302: Generate Parity Data

The RAID 6 controller 104 utilises a Reed-Solomon code is used to generate the parity information P and Q. The method proceeds to step 304. I

### Step 304: Allocate Version Number

The APP field 210 of each sector 200 of the stripe units is assigned a version number in accordance with the options outlined above. The version number may be, for example, 0 for a new stripe write.

The method then proceeds to step 306.

Step 306: Generate Version Vector

At step 306, the version vector for storage in the APP field 210 of the sectors of the parity block is generated from the version information of the blocks which that parity block protects.

Step 308: Write User Data to Sector

At step 308, the data 206 is written to the data area 202 of the respective sector 200. This includes writing the version information generated in step 304 to the APP field 210 of the respective sector 200.

The method then proceeds to step 310.

### Step 310: Write Parity Information

The parity information 208 generated in step 302 is then written to the data fields 202 of the parity blocks P and Q. In addition, the version vector for each respective parity block is also written to the APP field 210 of the parity sector.

The method then proceeds to step 312.

### Step 312: End

At step 312, the writing of the data 202 together with parity information is complete. The method may then proceed back to step 300 for further stripes or may terminate.

The steps of a partial stripe write of data to the RAID array will be discussed with reference to FIG. 8.

### Step 400: Write Request to Controller

At step 300, the host 102 generates a write request for a specific volume (e.g. storage device 106a) to which it has been assigned access rights. The request is sent via communication network 110 to the host ports (not shown) of the RAID controller 104. The write command is then stored in a local cache (not shown) forming part of the RAID controller hardware 120 of the RAID controller 104.

The RAID controller 104 is programmed to respond to any commands that request write access to the storage device 106a. The RAID controller 104 processes the write request from the host 102 and determines the target identifying address of the stripe to which it is intended to write that data to.

The method proceeds to step 402.

Step 402: Read Data from Corresponding Blocks

Prior to writing the data specified in the write command in step 400, the RAID controller 104 reads the data from the blocks of the other stripe units in the stripe to which the write command has been assigned in preparation for construction of an updated parity block.

The method proceeds to step 404.

### Step 404: Verify Parity

In step 404, before the data is written, the parity block is read to verify the version vector and the version numbers in the existing data.

### Step 406: Mismatch Detected?

At step 406, the version vector in the parity block is compared with the version information in the APP fields 210 of the data blocks. If a mismatch is detected, then the method proceeds to step 408. If no mismatch is detected, then the method proceeds to step 412.

### Step 408: Reconstruct Data

If a mismatch is detected in step 406, the incorrect data can be reconstructed from the existing fault-free data and the parity. If, for example, a lost write has occurred, then the parity block will comprise a higher version number than the data block. The data in that data block can then be reconstructed.

Alternatively, if a data block has a higher version number than a parity block, an error in the parity block may have occurred. The parity block can then be reconstructed for the other data blocks.

Once the data has been reconstructed, the method proceeds to step 410.

### Step 410: Generate Parity Data

The RAID 6 controller 104 utilises a Reed-Solomon code is used to generate the parity information P and Q from the new data to be written and the data read in step 402. The method proceeds to step 412.

### Step 412: Update Version Numbers

The version number of the newly-written blocks is updated by updating the version information stored in the APP field 210 of the sectors 200 associated with the data blocks.

### Step 414: Update Version Vectors

The updated version numbers of the newly-written blocks are then used to calculate an updated version vector in the APP field 210 of the parity blocks associated with the data blocks which have been modified. This may comprise a reduction function of the version information in the version vector to enable the version vector to be stored in the available space in the APP fields 210 of the parity sectors 200.

The method then proceeds to step 416.

### Step 416: Write Data Update

The data to be written to the respective blocks is then written to the drive, including writing the updated version information to the APP field 210 of the respective sectors 200. The method then proceeds to step 418.

### Step 418: Write Parity Data

The parity information generated in step 410 is then written to the data fields 202 of the parity blocks P and Q. The updated version vector generated in step 414 is also written to the APP field 210 of the respective parity sector at this step. The method then proceeds to step 420.

### Step 420: End

At step 420, the updating of the data 202 together with parity information is complete. The method may then proceed back to step 400 for further stripes or may terminate.

FIG. 9 shows a flow diagram of the method for reading data from the RAID array 108 which enables silent data corruption to be detected. However, the invention is equally applicable to a sector of a logical drive, or a RAID array of drives in which data is striped thereon.

### Step 500: Read Request to Controller

At step 500, the host 102 generates a read request for the RAID array 108 to which it has been assigned access rights. The request is sent via the communication network 110 to the host ports (not shown) of the RAID controller 104. The read command is then stored in a local cache (not shown) forming part of the RAID controller hardware 120 of the RAID controller 104.

### Step 502: Determine Sector of Storage Device

The RAID controller 104 is programmed to respond to any commands that request read access to the RAID array 108. The RAID controller 104 processes the read request from the host 102 and determines the sector(s) of the storage devices 106a-106j in which the data is stored. The method then proceeds to step 504.

Step 502: Read version information

Prior to reading the data specified in the read command in step 500, the RAID controller 104 reads the version information from the APP fields 210 of the data blocks.

The method proceeds to step 504.

### Step 504: Verify Parity

In step 504, before the data is read, the parity block is read to verify the version vector and the version numbers in the existing data.

Step 506: Mismatch detected?

At step 506, the version vector in the parity block is compared with the version information in the APP fields 210 of the data blocks. If a mismatch is detected, then the method proceeds to step 508. If no mismatch is detected, then the method proceeds to step 512.

### Step 508: Reconstruct Data

If a mismatch is detected in step 406, the incorrect data can be reconstructed from the existing fault-free data and the parity. If, for example, a lost write has occurred, then the parity block will comprise a higher version number than the data block. The data in that data block can then be reconstructed.

Alternatively, if a data block has a higher version number than a parity block, an error in the parity block may have occurred. The parity block can then be reconstructed for the other data blocks.

Once the data has been reconstructed, the method proceeds to step 510.

Step 510: Read Data The data can now be read as required. The method proceeds to step 512.

### Step 512: End

At step 512, the writing of the data 202 together with parity information is complete. The method may then proceed back to step 500 for further data reads or may terminate.

Variations of the above embodiments will be apparent to the skilled person. The precise configuration of hardware and software components may differ and still fall within the scope of the present invention.

For example, the present invention has been described with reference to controllers in hardware. However, the controllers and/or the invention may be implemented in software. This can be done with a dedicated core in a multi-core system.

Additionally, whilst the present embodiment relates to arrangements operating predominantly in off-host firmware or software (e.g. on the RAID controller 104), an on-host arrangement could be used.

Further, alternative ECC methods could be used. The skilled person would be readily aware of variations which fall within the scope of the appended claims.

Embodiments of the present invention have been described with particular reference to the examples illustrated. While specific examples are shown in the drawings and are herein described in detail, it should be understood, however, that the drawings and detailed description are not intended to limit the invention to the particular form disclosed. It will be appreciated that variations and modifications may be made to the examples described within the scope of the present invention.

1. A method of writing data to a data sector of a storage device, the data sector having at least one parity sector associated therewith, each sector being configured to comprise a data field and a data integrity field, the data integrity field comprising a guard field, an application field and a reference field, the method comprising:
providing data to be written to an intended sector;
generating, for said intended sector, version information for said sector;
generating a version vector based on said version information for said data sector; and
writing said data to the data field of the data sector;
writing said version information to the application field of the data sector;
writing said version vector to the application field of the parity sector.

2. A method according to claim 1, further comprising:
writing said data in units of blocks, wherein each block comprises a plurality of sectors.

3. A method according to claim 2, wherein each sector within a given block is allocated the same version number.

4. A method according to claim 1, wherein the version number of a sector is changed each time said sector is written to.

5. A method according to claim 4, wherein the version number is incremented each time the sector is written to.

6. A method according to claim 4, wherein the version number is changed randomly each time the sector is written to.

7. A method according to claim 6, wherein the version number is changed randomly for all blocks.

8. A method according to claim 6, wherein the version number is changed randomly independently for each block or group of blocks.

9. A method according to claim 4, wherein the version number is incremented and randomly selected.

10. A method according to claim 2, further comprising:
writing said data in units of stripe units, each stripe unit comprising a plurality of blocks.

11. A method according to claim 10, wherein said intended sector comprises part of a stripe unit and the method comprises, after said step of providing:
reading version information from stripe units associated with said stripe unit;
reading the version vector associated with said stripe units;
determining whether a mismatch has occurred between the version information and the version vector and, if a mismatch has occurred, correcting said data.

12. A method according to claim 1, wherein said version vector comprises the version information for each data sector.

13. A method according to claim 12, wherein said version vector comprises a reduction function of said version information.

14. A method according to claim 1, wherein the or each data sector is in accordance with the T10 format.

15. A method of reading data from a sector of a storage device, the data sector having at least one parity sector associated therewith, each sector being configured to comprise a data field and a data integrity field, the data integrity field comprising a guard field, an application field and a reference field, the method comprising:
executing a read request for reading of data from a data sector;
reading version information from the application field of said data sector;
reading version vector from the application field of a parity sector associated with said data sector;
determining whether a mismatch has occurred between the version information and the version vector and, if a mismatch has occurred, correcting said data; and
reading the data from said data sector.

16. A method according to claim 15, wherein the or each data sector is in accordance with the T10 format.

17. A controller operable to write data to a data sector of a storage device, the data sector having at least one parity sector associated therewith, each sector being configured to comprise a data field and a data integrity field, the data integrity field comprising a guard field, an application field and a reference field, the controller being operable to provide data to be written to an intended sector, generate, for said intended sector, version information for said sector, to write said data to the data field of the data sector, to write said version information to the application field of the data sector, to generate a version vector based on said version information for said data sector; and to write said version vector to the application field of the parity sector.

18. A controller operable to read data from a sector of a storage device, the data sector having at least one parity sector associated therewith, each sector being configured to comprise a data field and a data integrity field, the data integrity field comprising a guard field, an application field and a reference field, the controller being operable to execute a read request for reading of data from a data sector, to read version information from the application field of said data sector, to read a version vector from the application field of a parity sector associated with said data sector, to determine whether a mismatch has occurred between the version information and the version vector and, if a mismatch has occurred, to correct said data and to read the data from said data sector.

19. Data storage apparatus comprising at least one storage device and the controller of claim 17.

20. Data storage apparatus comprising at least one storage device and the controller of claim 18.

21. A storage protocol for storage of data, the storage protocol comprising a data sector format comprising a data field and a data integrity field, the data integrity field comprising a guard field, an application field and a reference field, wherein data sectors in accordance with said storage protocol are configured to store version information in said application field, said version information being modified when said sector is modified.

22. A storage protocol according to claim 19, wherein said data sectors are associated with at least one parity sector, the application field of said parity sector being configured to store a version vector representing the version information for the or each data sector associated with said parity sector.

23. A storage protocol according to claim 19 in the form of a T10 storage protocol.

24. A computer program product executable by a programmable processing apparatus, comprising one or more software portions for performing the steps of any one of claim 1.

25. A computer program product executable by a programmable processing apparatus, comprising one or more software portions for performing the steps of claim 15

26. A computer usable storage medium having a computer program product according to claim 24 stored thereon.

27. A computer usable storage medium having a computer program product according to claim 25 stored thereon.
